(19) United States
(12) Patent Application Publication
(10) Pub. No.: US 2023/0059403 A1
(43) Pub. Date: Feb. 23, 2023

(54) WAVELENGTH CONVERSION OPTICS

(71) Applicant: Magna Rohinni Automotive, LLC, Holly, MI (US)

(72) Inventor: Edward Bailey, Rochester Hills, MI (US)

(21) Appl. No.: 17/891,493

(22) Filed: Aug. 19, 2022

Related U.S. Application Data
(60) Provisional application No. 63/234,915, filed on Aug. 19, 2021.

(51) Int. Cl. H01L 33/50

(52) U.S. Cl. CPC H01L 33/504; H01L 33/505; H01L 2933/0041; H01L 25/13

(57) ABSTRACT

A wavelength conversion device includes an LED chip. A PCB solder mask defines an opening at least partially encompassing the LED chip. A lens is optically coupled with the LED chip and includes phosphor particles, emulsifier particles, and lens shaping particles each immersed within the lens. In various instances, the wavelength conversion device may be operably coupled with a vehicle to form various light effects.

### CROSS-REFERENCE TO RELATED APPLICATION

This application claims the benefit of priority to U.S. Provisional Patent Application No. 63/234,915, entitled “WAVELENGTH CONVERSION PRIMARY OPTICS”, filed on Aug. 19, 2021, the disclosure of which is hereby incorporated by reference herein in its entirety for all purposes.

### FIELD

The present disclosure relates to light emitting diodes (“LEDs”) and a method of fabricating the same, and more particularly, to improvements directed towards wavelength conversion.

### BACKGROUND

LEDs offer numerous benefits over legacy lighting components. For example, LEDs can offer long operating life of 50,000 to 100,000 hours as compared to 500-1500 hours for incandescent filaments and cost reductions on vertical flip-chip LED devices have enabled the application of the devices to a wider range of operating conditions tailored to automotive, mobility, and military.

Over the operating life of a vehicle (e.g., 10-20 years), inorganic LEDs offer the best solution today to producing reliable high luminance (candela/m²) white light through blue chip pumped phosphors. Low-cost 5630 and 3030 packaged LED's in general lighting has dominated as cost reduction further allows increased adoption of solid-state lighting technology in the marketplace.

There is a need for uniform light wavelength converted from violet, blue, and cyan excitation to broad spectrum light using phosphors. In the simplest of terms, the phosphor is what makes LED light usable. LED chips are intrinsically blue, red, or green with the blue variety of LEDs being the most commonly used in solid-state lighting. Blue LED's such as InGaN grown on c-plane patterned sapphire substrates produce the highest EQE approaching 82%. However, the blue light produced is not usable for many lighting applications and can be covered with a phosphor, which absorbs the blue emission from the LED and re-emits light at longer wavelengths, appearing as white light.

However, the phosphor particles being a higher index produce scattering. As such, it can become challenging to control the optical distribution of the wavelength converted light. Accordingly, there is a need for various structures that can allow for more control of the light scatter.

### BRIEF DESCRIPTION

Aspects and advantages of the technology will be set forth in part in the following description, or may be obvious from the description, or may be learned through practice of the technology.

In some aspects, the present subject matter is directed to a wavelength conversion device comprises an LED chip and a PCB solder mask defining an opening at least partially encompassing the LED chip. A lens is optically coupled with the LED chip and including phosphor particles, emulsifier particles, and lens shaping particles each immersed within the lens.

In some aspects, the present subject matter is directed to a method for manufacturing a wavelength conversion device. The method includes producing a trillion shaped LED chip. The method also includes applying a conformal phosphor coating to the LED chip. Lastly, the method includes optically coupling a lens having quantum dots (QDs) with the LED chip.

In some aspects, the present subject matter is directed to a lighting system that includes a first wavelength conversion device that comprises a first trillion-shaped LED chip having three lateral sides, wherein the first trillion-shaped LED chip defines edge bevels between adjacent sides of the three lateral sides. A first lens is optically coupled with the first trillion-shaped LED chip. The first lens includes a first side portion, a second side portion, and a third side portion. The first and second portions are a common distance from the first trillion-shaped LED chip and the third portion is a varied distance from the first trillion-shaped LED chip.

These and other features, aspects, and advantages of the present technology will become better understood with reference to the following description and appended claims. The accompanying drawings, which are incorporated in and constitute a part of this specification, illustrate embodiments of the technology and, together with the description, serve to explain the principles of the technology.

### BRIEF DESCRIPTION OF THE DRAWINGS

A full and enabling disclosure of the present technology, including the best mode thereof, directed to one of ordinary skill in the art, is set forth in the specification, which makes reference to the appended figures, in which:

FIG. 1 depicts an LED with phosphor in a cup and epoxy lens in accordance with various aspects of the present disclosure;

FIG. 2 depicts a 3030 LED with phosphor in a tub in accordance with various aspects of the present disclosure;

FIGS. 3A-3D depict a wavelength converting primary optic with a circular shape in accordance with various aspects of the present disclosure;

FIGS. 4A-4B depict a wavelength converting primary optic with a rounded square shape in accordance with various aspects of the present disclosure;

FIGS. 5A-5D depicts a wavelength converting primary optic with an asymmetric rectangular shape in accordance with various aspects of the present disclosure;

FIGS. 6A and 6B depicts a wavelength converting primary optic with collimation shape in accordance with various aspects of the present disclosure;

FIGS. 7A-7C depict a wavelength converting primary optic arrange in an array with a triangular shape in accordance with various aspects of the present disclosure;

FIGS. 8A-8D depict a wavelength converting primary optic with a triangular shape and quantum dot/phosphors in accordance with various aspects of the present disclosure;

FIGS. 9A-9E depict a wavelength converting primary optic with a triangular shape, trillion LED, and QD remote color tuning in accordance with various aspects of the present disclosure;

FIG. 10 depicts advanced lighting systems on a vehicle from a front perspective in accordance with various aspects of the present disclosure;

FIG. 11 depicts advanced lighting systems on a vehicle from a rear perspective in accordance with various aspects of the present disclosure;

FIG. 12 depicts advanced lighting systems on an interior of a vehicle in accordance with various aspects of the present disclosure; and

FIG. 13 depicts a method for manufacturing a wavelength conversion device in accordance with various aspects of the present disclosure.

Repeat use of reference characters in the present specification and drawings is intended to represent the same or analogous features or elements of the present technology.

### DETAILED DESCRIPTION

Reference now will be made in detail to embodiments of the disclosure, one or more examples of which are illustrated in the drawings. Each example is provided by way of explanation of the discourse, not limitation of the disclosure. In fact, it will be apparent to those skilled in the art that various modifications and variations can be made in the present disclosure without departing from the scope or spirit of the disclosure. For instance, features illustrated or described can be used with another embodiment to yield a still further embodiment. Thus, it is intended that the present disclosure covers such modifications and variations as come within the scope of the appended claims and their equivalents.

In this document, relational terms, such as first and second, top and bottom, and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

As used herein, the terms “first,” “second,” and “third” may be used interchangeably to distinguish one component from another and are not intended to signify a location or importance of the individual components. The terms “coupled,” “fixed,” “attached to,” and the like refer to both direct coupling, fixing, or attaching, as well as indirect coupling, fixing, or attaching through one or more intermediate components or features, unless otherwise specified herein. The term “selectively” refers to a component's ability to operate in various states (e.g., an ON state and an OFF state) based on manual and/or automatic control of the component.

As used herein, an “x-direction” corresponds to a length (e.g., a long dimension) of a LED chip, a “y-direction” corresponds to a width of a LED chip, and a z-direction corresponds to a vertical distance from a LED chip in which the z-direction is ortho-normal to the plane of active light emitting multiple quantum wells. In addition, “pitch” corresponds to a chip-to-chip distance between two LED chips in one of their x-direction and their y-direction.

Furthermore, any arrangement of components to achieve the same functionality is effectively “associated” such that the functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected” or “operably coupled” to each other to achieve the desired functionality, and any two components capable of being so associated can also be viewed as being “operably couplable” to each other to achieve the desired functionality. Some examples of operably couplable include, but are not limited to, physically mateable, physically interacting components, wirelessly interactable, wirelessly interacting components, logically interacting, and/or logically interactable components.

The singular forms “a,” “an,” and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about,” “approximately,” “generally,” and “substantially,” is not to be limited to the precise value specified. In at least some instances, the approximating language may correspond to the precision of an instrument for measuring the value, or the precision of the methods or apparatus for constructing or manufacturing the components and/or systems. For example, the approximating language may refer to being within a ten percent margin.

Moreover, the technology of the present application will be described in relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

As used herein, the term “and/or,” when used in a list of two or more items, means that any one of the listed items can be employed by itself, or any combination of two or more of the listed items can be employed. For example, if a composition or assembly is described as containing components A, B, and/or C, the composition or assembly can contain A alone; B alone; C alone; A and B in combination; A and C in combination; B and C in combination; or A, B, and C in combination.

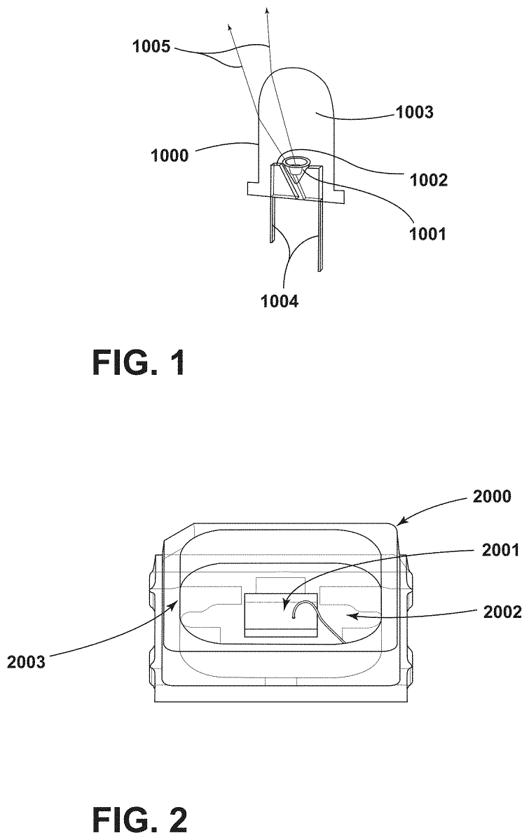

FIG. 1 shows an LED 1000 (e.g., 5 mm) comprised of an LED chip 1001 immersed in a conical epoxy cavity/cup shaped by a cathode lead frame 1004.

An LED phosphor 1002 may be contained in the conical cavity that can enable the conversion of blue light from blue to cool white or other broadband spectra.

In the illustrated example, light rays 1005 emerging from LED lens 1003 receive some collimation (e.g., making a bundle of light rays parallel) using the plastic lens shape and the rays 1005 which emerge have higher intensity cd/lm than the original LED chip 1001.

In some instances, this design of an LED 1000 cannot thermally dissipate heat other than through the wire lead frame 1004. Heat dissipation may be important, for example, because it increases the working life of the LED and affects the brightness of the emitted light.

In addition, wavelength conversion may be non-uniform emerging from the lens, sometimes producing light striations 1003, e.g., long thin parallel streaks of light.

In certain applications, these light striations are acceptable but for automotive applications, where high color uniformity is desired and sometimes necessary, the requisite high color uniformity is not possible without secondary diffusers. However, diffuser films present problems, including light loss as light passes through another surface.

FIG. 2 shows an LED 2000 (e.g., 3030 chip package) including an LED chip 2001 that may be wire bonded from the top to an over-molded lead frame package 2004.

The chip 2001 may emit blue light, which is then phosphor converted using phosphor particles, which may be mixed within a silicone (or any other practicable material) and particles 2002 immersed in tub 2003. The thickness of the path of the light from the LED chip 2001 to the edge of the reflector is not equidistant due to the shape of the tub 2003. Thus, some light undergoes more wavelength conversion than other light which can result in color non-uniformity problems. These color uniformity issues are noticeable due to the cooler white over the top of the chip and the green and yellow color of the light laterally surrounding the chip. Also the 3030 LED produces lower luminance due to the large tube of phosphor conversion material source broadening.

However, the design does not offer any optical control other than recycling/reflecting the light through the side edge tub (reflective surface) which may have some slope but limited light control capability.

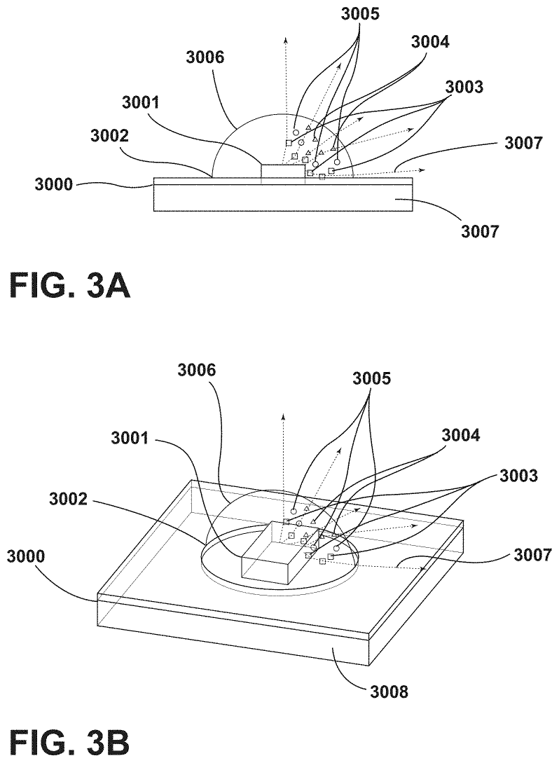

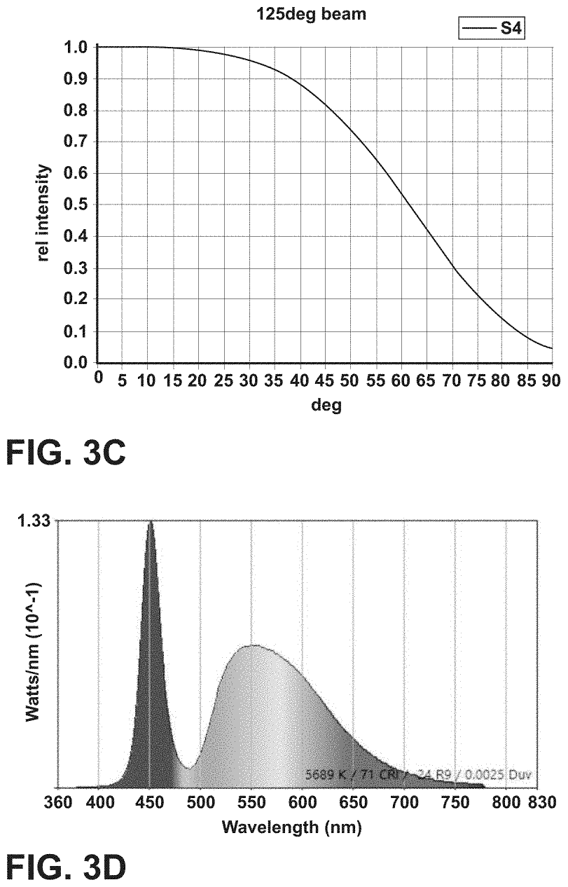

FIGS. 3A-3D show a wavelength conversion device including a wavelength conversion primary optic 3000 comprising a number of elements, including an LED chip 3001, a circular shaped PCB solder mask opening 3002, which is shown partially removed to create a constraining cavity (e.g., circular opening), and particles 3003, 3004, 3005 of three different species (described below) immersed in a silicone-based lens 3006, e.g., high refractive index greater than or equal to 1.5.

In various examples, the particles may be comprised of LED phosphor particles 3003, LED emulsifier particles 3004, and/or LED lens shaping particles 3005. When combined in function, a particle loading consisting of, for example, 20-65% phosphor particle 3003 loading by mass, and 0.3-1.5% emulsifier particles 3004 and combined with lens shaping particles 3005 of weight % 1-10% with the unique shape of the silicone-based lens 3006, can produce a controlled light distribution 3009, which can be Lambertian or Gaussian, as required for a desired illumination task. Lens shaping particles 3005 if not included in the mix produce more difficult in maintaining a defined optical shape as settling occurs during curing of the silicone lens. Lens shaping particle distributions help to maintain or customize the viscosity of the composite material to direct the light by controlling the height of the lens material over the chip. Furthermore without lens shaping particles the silicone lens shape is entirely dependent on the viscosity of the silicone material and greater variation of the height of the lens over the chip is likely 30-50% which impact light extraction efficiency and the distribution of the light which can reduce the light control capabilities of the secondary optics.

As shown in FIG. 3D, for example, the result is a spectral light distribution 3010 which could include combinations of blue, cyan, or violet light and higher wavelengths in green, yellow, red, and infrared to produce pleasing white light or monochromatic light using luminescence.

As shown in FIGS. 3A and 3B, the LED chip 3001 is attached to PCB substrate 3008, which can comprise a copper (Cu) interconnect to electrify the LED chip 3001. The PCB substrate 3008 may be produced from ceramic, glass, fr4, CEM3, and/or any other practicable material. The materials may be thermally conductive, such as k greater than or equal to 0.7, and can be greater than 1.0 deg C./W of low CTE less than or equal to 30 ppm/deg C. (coefficient of thermal expansion), and flexible to some degree to conform to free-form shapes.

In various examples, the LED chip 3001 may be soldered to a circuit board having one or more traces (e.g., the ENIG traces). In some instances, individual traces electrify the LED chips individually at a tight pitch (e.g., as close as approximately 0.2 mm) to enable a higher resolution display capable of illustrating graphics, such as pictograms, text, and numerals, and/or any other information. Moreover, the LED chip 3001 may each be configured as an LED chip on board (COB). In some examples, the LED COB can be designed to occupy 100-350 μm (e.g., mini chips) and 2-100 μm (e.g., microchips). In addition, configurations of micro LED chips with a size of less than 50 μm may have a sapphire or Si substrate removed, such as by UV excimer or via grinding etch, or polishing may be utilized. In some instances, by using an LED chip on board versus a standard 3030 or 3.0×3.0 mm package, a light source that is less than 1% the original size (e.g., 0.06 mm² or (350×170 μm chip)/9 mm²=<1%) may be used within the lighting system . Otherwise stated, the space savings of each LED chip on the circuit board can be over 99% when compared to a standard 3030 or 3.0×3.0 mm package.

The LED phosphor particles 3003 may be arranged as a coating, layer, film, or other suitable deposition. In various examples, the LED phosphor 3004 may include at least one energy-converting element with luminescent properties. For example, the LED phosphor particles 3003 may be comprised of YAG, LuAg, GAL, KSF, Si₃N₄. SiAlON:Eu2+, K2SiF6:Mn4+ and/or other materials. In various examples, the particle size D50 can range between 5 μm and 20 μm. In general, a larger particle size results in higher quantum efficiency, but a smaller size particle may also be used to result in tighter packing density near the LED chip 3001 for thermal transfer of the non-radiative heat produced through wavelength conversion. The shape and orientation of the LED phosphor particles 3003 affect efficiency.

Additionally or alternatively, a fluorescent material may be operably coupled with the LED chip 3001 and may include at least one energy-converting element with fluorescent (or otherwise luminescent) properties. In some examples, the fluorescent material may include organic or inorganic fluorescent dyes including rylenes, xanthenes, porphyrins, phthalocyanines.

To produce uniform wavelength converted color, the particles 3003, 3004, and 3005, for example, may be uniformly distributed so that the uniform path length of the pump light results in uniform wavelength conversion. The density and spatial distribution of the phosphor conversion particles 3003 have a dramatic effect on the wavelength of the light. The emulsifier particles 3004 modify the refractive index of the silicone and reduce the clumping or agglomeration of the phosphor particles.

The LED emulsifier particles 3004 may be comprised of SiO2, CaF, ZrO₂, and TiO₂, and may have particle sizes that may be between nano size (15-50 nm) and (micro-sized 5-20 μm) ranges. For example, mixing through a centrifugal vacuum mixer at high speed can disperse the emulsifier particles 3004 uniformly within the silicone composite and when loaded 0.5-1% can increase the refractive index of the silicone from 1.4 to 1.46 to 1.52. These nano-size particles, for example, the emulsifier particles 3004, such as ZrO₂ and TiO₂ raise the index of refraction of the material composite to better match the LED phosphor particles 3003 thereby reducing scattering and enhancing light distribution control of the silicone-based lens 3006.

The LED lens shaping particles 3005 may be comprised of nano-sized hydrophobic fumed silica or SiO₂, Si₂N₂, or other Pb-free borosilicate glass particles

In some examples, the LED lens shaping particles 3005 may have a D50 particle size between 8-30 nm. Moreover, the LED lens shaping particles 3005 may be surface modified to be extremely hydrophobic thereby repelling electrostatic effects which tend to bind and clump the phosphor particles 3003 together resulting in undesirable scattering and loss of optical control. The nano-sized fumed silica also allows for greatly increased concentration by weight % of the loading possible within the silicone composite.

Whereas in FIG. 2 the tub of silicone may only include 0.5-1% of particle loading, with nano-size fumed silica the particle loading may increase to as high as 7% which serves to control the viscosity of the silicone and thereby control the height and shape of the lens 3006. For example, rather than using a high viscosity silicone of cP near 7500, a much lower silicone viscosity of 1200 can be used to increase piezoelectric jet dispersing speed from 1 hertz (Hz) dots to greater than or equal to 25 Hz, which can reduce cycle time and cost of an LED product comprised of many mini-chip LED's. The silicone material can have a high transmission in violet 365 nm to deep red 680 nm of greater than or equal to 95 percent to improve wavelength conversion efficiency when operated at high temperature, e.g., 150 degrees Celsius (° C.).

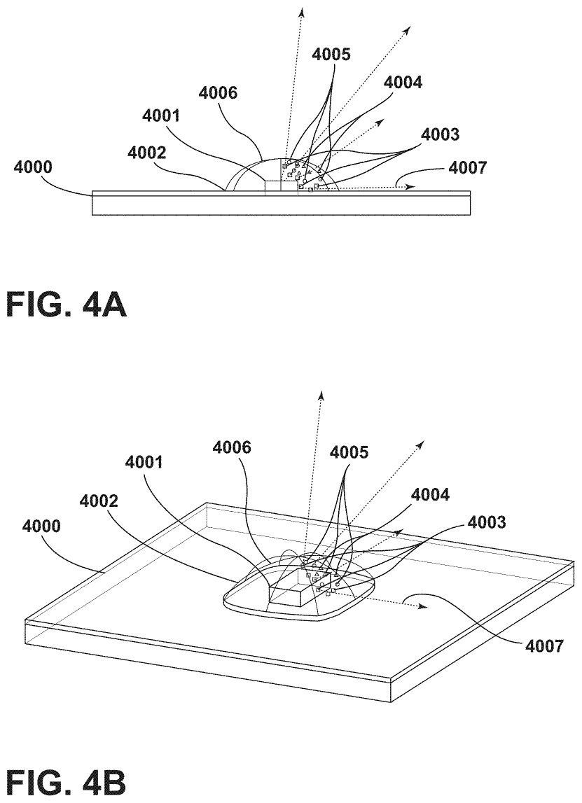

FIGS. 4A and 4B show a wavelength conversion device 4000 that includes an LED chip 4001 attached to PCB substrate 4008, elongated squircle (e.g., Fernandez-Guasti of order S=0.9, variations in the range of the S parameter could range from 0.1 to 0.99) LED solder mask opening 4002, LED phosphor particles 4003, LED emulsifier particles 4004, and LED lens shaping particles 4005, which when mixed with silicone of silicone-based lens 4006 encapsulate and protect the LED chip 4001.

The light rays which emerge from the silicone-based lens 4006 are wavelength converted to produce a longer wavelength, or broadband light with light distribution which produces white or longer wavelength monochromatic colors such as red, red/orange, amber, or signal yellow (e.g., about 580 nm). Phosphor converted lime and aqua-green colors are also possible by controlling the mix of phosphors and the weight % of each. For example, by loading 15-35% of peak wavelength 522 nm phosphor or 555 nm phosphor, a green color can be produced which when combined with blue light which passes unconverted through the lens can produce a brilliant lime or aqua green which when combined with deep blue in 445 nm and deep red at 650 nm can expand the chromaticity gamut, such as by greater than or equal to 100% NTSC. The enhancement of the solder mask opening 4002 to the shape described in this embodiment, for example, helps to control the light evenly in both directions to produce equidistant paths for the pump light to traverse when undergoing wavelength conversion so that uniform luminescence distributes the light.

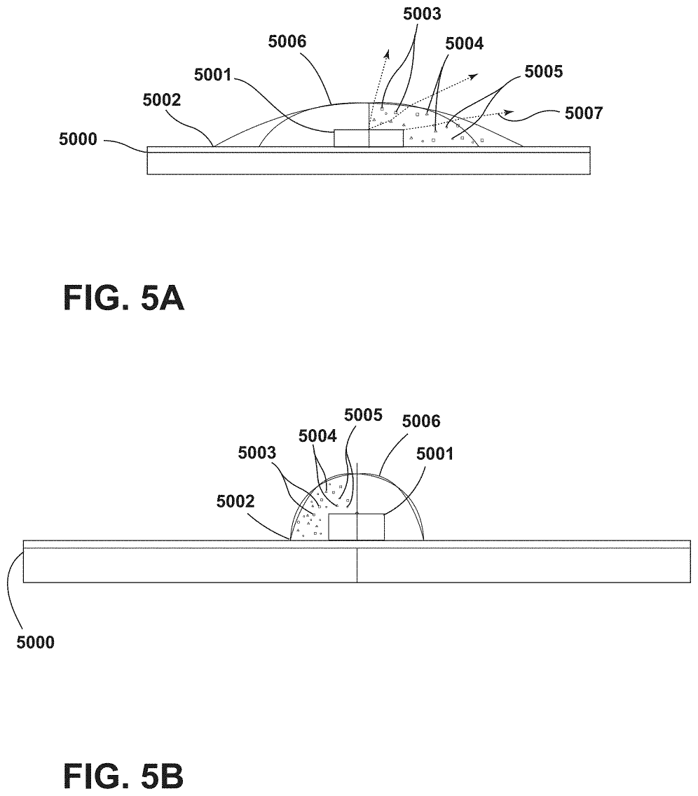

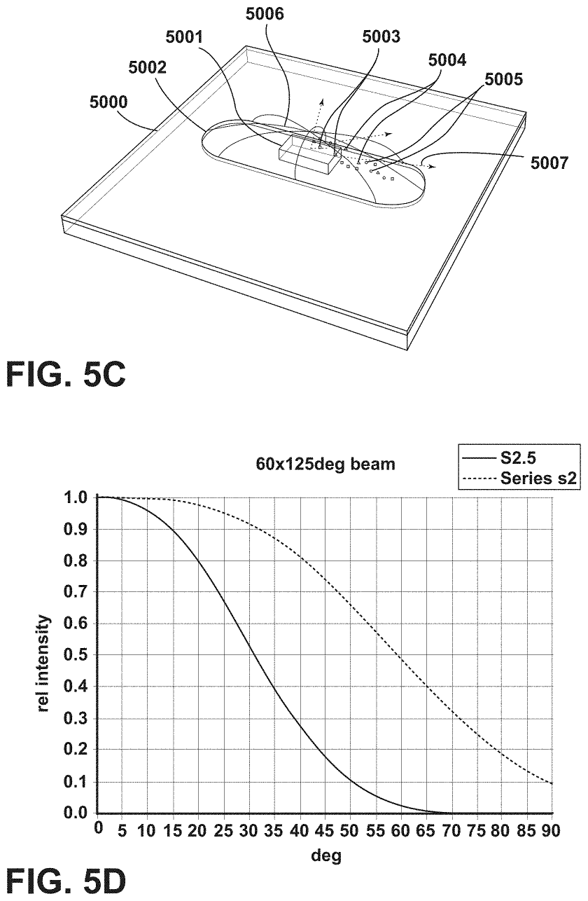

FIGS. 5A-5D shows an embodiment including a wavelength conversion device 5000 comprising LED chip 5001, a pill shape (e.g., oblong) solder mask opening 5002, and a mix of primarily three classes of particles including LED phosphor particles 5003, LED emulsifier particles 5004, and LED lens shaping particles 5005 (e.g., which serve some emulsification purpose as well) immersed in a pill shape (e.g., oblong) silicone-based lens 5006.

One purpose of the shape of the silicone-based lens 5006 is to produce asymmetry in light distribution rays 5007 so that it is more collimated in one axis as compared to the cross-section direction. This asymmetry produces a more elliptical beam 5008 (e.g., asymmetrical) which may be necessary, for example, for one or more fog, low beam, and rear stop functions for automotive applications.

In FIG. 5D, for example, S2.5 (lower line) represents the intensity of a 62-degree beam in a vertical direction, and Series2 (upper line) represents the intensity of a 120-degree horizontal distribution of the light after passing through the wavelength conversion lens 5006.

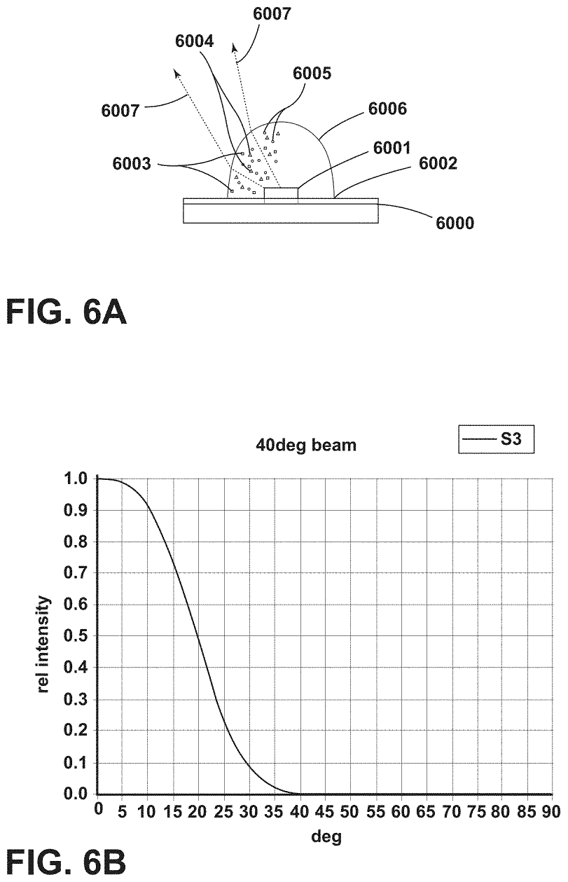

FIGS. 6A-6B show a wavelength conversion device 6000 comprising LED chip 6001, a circular or rounded square shape solder mask opening 6002, and three primary classes of particles, namely LED phosphor particles 6003, LED emulsifier particles 6004, and LED lens shaping particles 6005 loaded into silicone-based lens 6006.

The overall shape of the silicone-based lens 6006 in this embodiment produces a collimation function, e.g., 6007. Collimation, for example, refers to the lens shape with increased intensity or candela/lumen (cd/1 m) from Lambertian typically 0.3 cd/lm to higher intensity of 2 cd/1 m, or even 10 cd/1 m, depending on the shape of the lens.

In this design configured for collimation, as shown in FIG. 6A, a center section of the lens has a longer path length as compared to the sides so phosphor particle concentration 6003 by weight is reduced as the excitation light has more path length to traverse for wavelength conversion the probability of striking a phosphor particle is increased. To maintain a high conical shape, for example, a higher weight % of lens shaping particles 6005 may be used, e.g., 3 percent to 12 percent.

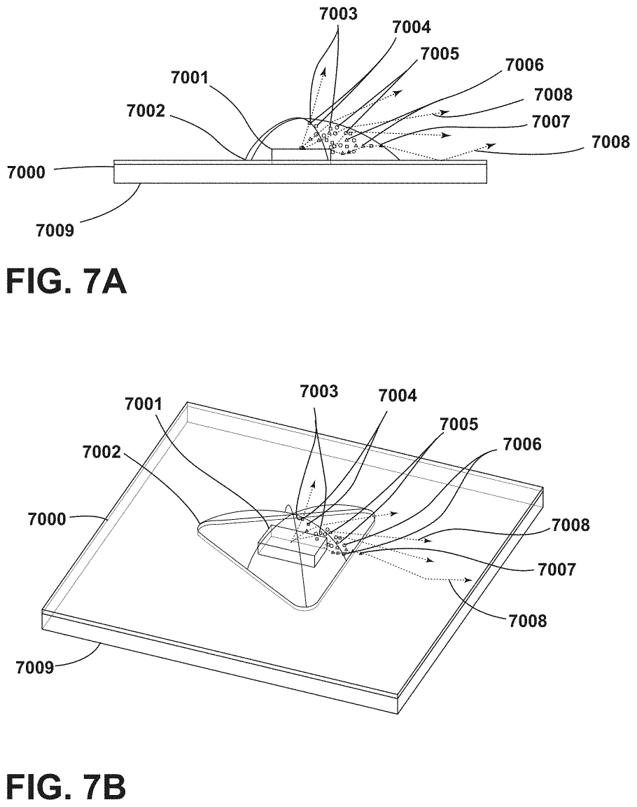

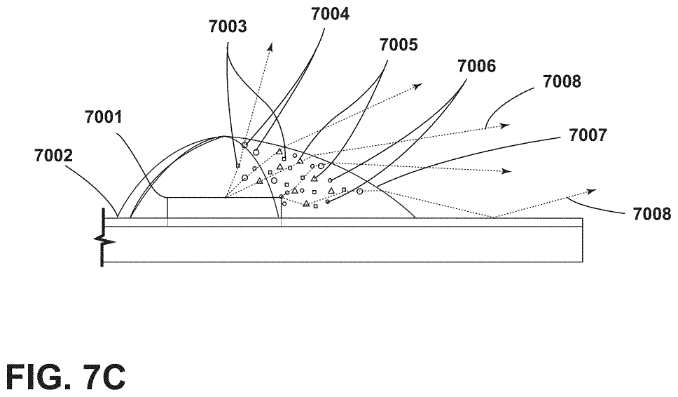

FIGS. 7A-C depict a wavelength conversion device including a change in solder mask opening 7002 (triangular shaped) that allows a wavelength conversion lens 7000 to produce a scatter lit aperture which when lit strikes the side wall and produces a shape of light slightly different than a rectangular LED chip 7001. In various examples, the LED phosphor particles 7003 can convert violet-cyan light into longer wavelength green to deep red. When trillion shaped light emitting diodes or pixels are combined with square or rectangular shaped light emitters enhanced display graphics, fonts, pictograms can be produced by manipulation of the light at the emitter stage allowing near field enhancement (reduced moire, aliasing, screen-door effect) as compared to classical pentile arrangement of multi-color pixels, or pixel groups.

In some examples, an addition of quantum dots, which may have a size of 1 nm to 12 nm as compared to the D50 of LED phosphor particles 5-20 μm. 7003 produces color tuning of the light emerging from the cool white YAG phosphor particles 7003. The quantum dots can be more temperature sensitive than YAG phosphor and locating them remotely from the chip is beneficial for quantum conversion efficiency.

Some quantum dot materials include an InP core, a thick inner shell of ZnSe, or a thin outer shell geometry of zinc sulphide (ZnS). Other materials utilized for producing quantum dots include Mn: ZnSe, CuInS_{2/}ZnS, InP/ZnS, and perovskites (e.g., CaTiO₃ (calcium titanium oxide)).

The LED emulsifier particles 7005 can prevent agglomeration of the particles into clumps, which can dramatically affect light ray paths 7008 and can produce undesirable striations.

The LED lens shaping particles 7006, for example, when loaded in concentration 1 percent to 10 percent within the silicone encapsulant allow high modification of viscosity of the silicone and lens shaping capability while also allowing piezoelectric jetting at high speed, e.g., 20 Hz to 100 Hz and higher.

The lens shape can enhance light extraction 7007 from the LED chip 7001. In some examples, light rays 7008 can strike orthonormal to the curvature of the lens to reduce backscatter at the polymer/air interface.

In this embodiment, the LED chip 7001 is attached to a thermally conductive substrate 7009 which allows the LED chip 7001 to function at higher drive current and luminous intensity.

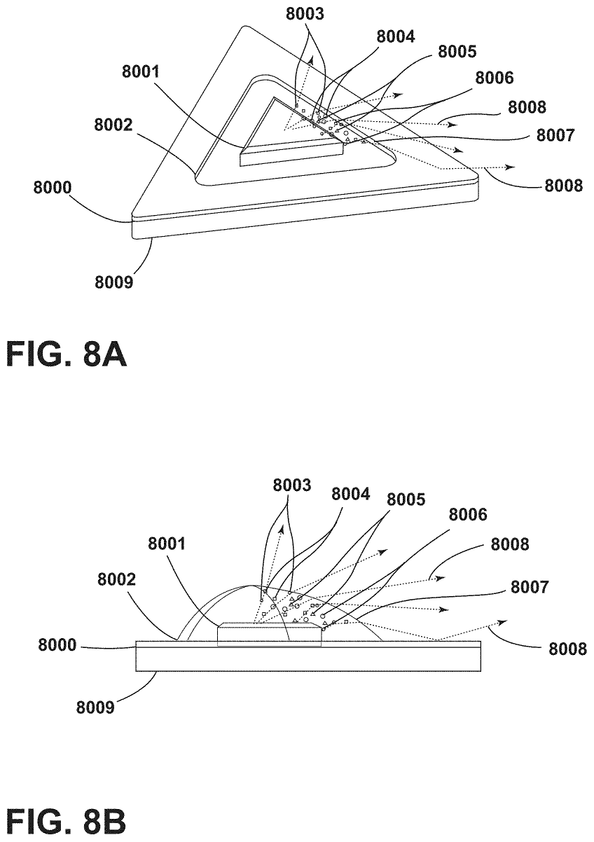

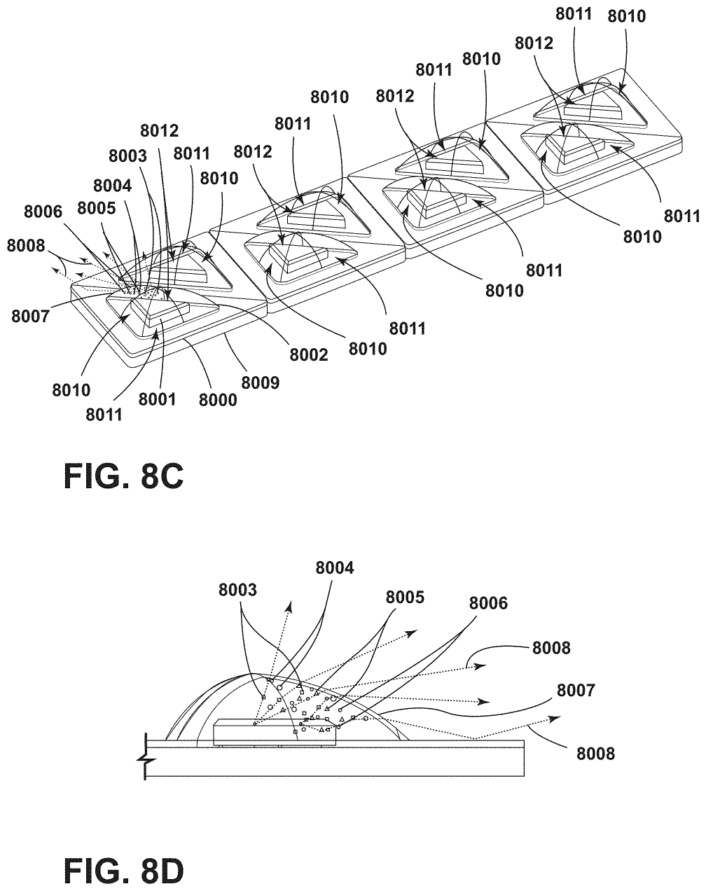

FIGS. 8A-8D depict a wavelength conversion device including a triangular wavelength conversion multi-cavity lens 8000 in which triangular cavities are grouped in a line, e.g., FIG. 8C.

In the illustrated embodiment, a trillion-shaped LED chip 8001 comprises three lateral sides to improve light extraction at a small size and may also include edge bevels to reduce backscatter due to total internal reflection at a sharp corner. Bevels can be produced through laser scribe and diamond saw when dicing the LED wafer. An additional advantage of the beveled trillion shape can be to reduce total internal reflection trapping within the Sapphire, SiC, or glass LED substrate which can be higher index of refraction as compared to surrounding environment of air or water.

In this embodiment, the triangular-shaped solder mask 8002 is designed to match the trillion-shaped LED chip 8001 to help shape and hold the shape of the wavelength conversion lens material in which the lens material is loaded with particles including phosphor particles 8003, quantum dots 8004, emulsifiers 8005, and lens shaping particles 8006 which aid in lens shaping.

The lens shape 8007 can affect the light extraction. Moreover, wavelength tuning may be utilized as the path lengths are changed according to the pump light incident on the wavelength converters, lumiphores, or quantum dots. In various examples, the lens associated with each LED chip 8001 may include a first side portion 8010, a second side portion 8011, and a third side portion 8012. In some instances, the first side portion 8010 and the second side portion 8011 may be a common distance from the LED chip 8001 and the third side portion 8012 may be a varied distance from the LED chip 8001 when compared to the distance between the first side portion 8010 and the LED chip 8001 and/or the second side portion 8011 and the LED chip 8001.

Quantum dots change the wavelength of LED light rays 8008 incident from a slightly altered wavelength emerging from the chip 8002 or phosphor particle scatter 8003 by adding some luminescence in specific bands. The LED substrate/PCB interconnects and electrifies the array of LED chips in parallel, series, and z-circuit formation to produce variable forward voltage and LED controls from single pixel control to zonal groups depending on the animation effects desired.

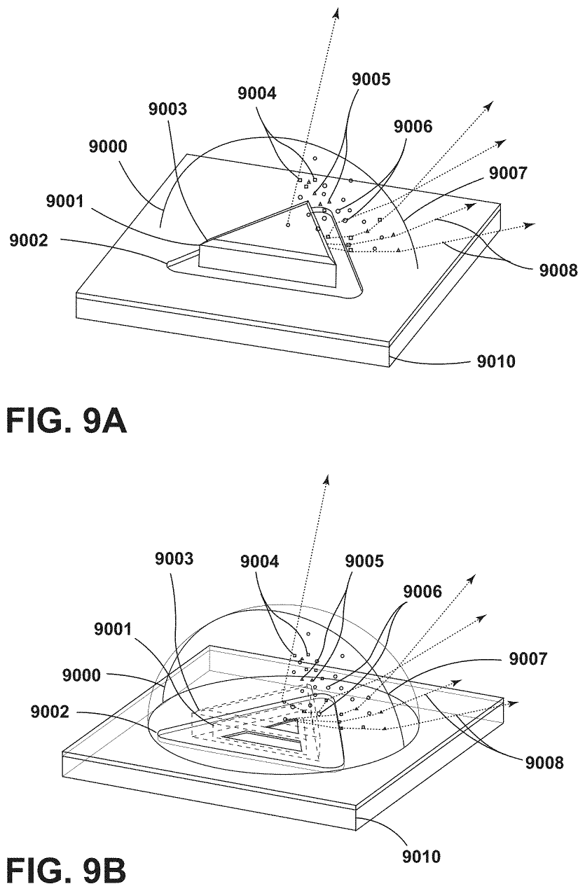

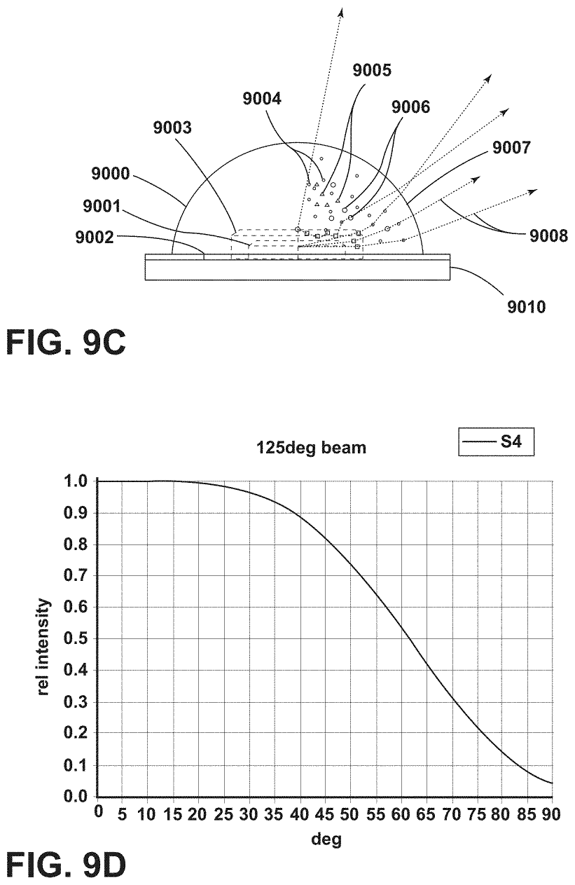

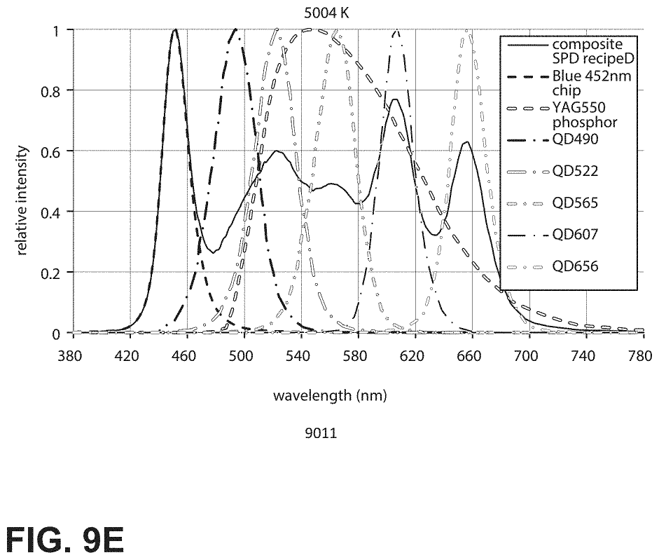

FIGS. 9A-9E depict a wavelength conversion device including wavelength conversion lens 9000 which comprises trillion-shaped LED chip 9001 with edge beveling to improve light extraction, triangular solder mask opening 9002 to shape and form the shape of the lens 9000 and 9007 to extract light from the LED chip 9001.

In this embodiment, conformal phosphor coating 9003 is applied directly to the LED chip 9001 to improve thermal dissipation through the sapphire substrate chip direct through the PCB interconnect and substrate. The light after passing through the conformal phosphor coating will leak some pump light violet-cyan in color which can pump the luminescence process of the quantum dots thereby performing color tuning.

By combining conformal phosphor coatings with quantum dots a wide variety of spectra, CCT, colors, and CRI are possible. For example, as shown in spectral distribution 9011 (FIG. 9E), the spectra produces an ideal white 5000K, with high color rendition greater than or equal to 95 CRI. Other daylight approximating spectra can be produced by varying the mix and color of primary excitation wavelengths and luminescent materials including the production of warm white flame color at 1700-2200K, to cool daylight white at D65 or 6500K. The advantage of quantum dots 9004 is that the color tuning reduces scattering as compared to larger particle phosphors 9003. When creating warm whites for example it is advantageous to reduce the FWHM or full width half max spectral bandwidth of the orange, or red luminescence to reduce loss in the infrared which is not converted to lumens by the opsins of the m-cones of the human eye. The spectra of the light emitters may also be designed to cancel out the color shift produced by the paint layers deposited upon the grille, bumper, or exterior body panels of a vehicle.

The exiting light rays 9008 are a combination of colors that create an ensemble of color or superposition of blended spectra to produce high uniformity broad-band white which replicates any color in reflection. Alternatively the QD or QD and phosphor mix may be used for adjusting the spectra of the light to compensate for color shifting within an exterior grille, or bumper cover paint. Multi-layer paints deposited on these grille or bumper components when laser ablated to create micro windows of transparency can improve efficiency of the transmitted light, but some color shifting will occur passing through thin paint layers. By combining specially tuned luminescent light from the LED the spectral composite which emerges can be tuned to produce a pleasing white light or primary color which is not green, or blue shifted.

The LED substrate/PCB 9010 conducts heat away from the chip to improve luminous efficacy (lumens/watt) which allows for power saving. The light distribution 9009 (FIG. 9D) represents a super-gaussian distribution with S parameter=4 in which the intensity distribution over angle 0 degrees to 90 degrees can be described by equation (1):

$$I ( r ) = {Io}^{- 2 {( \frac{r}{w s} )}^{S}} , \qquad ( 1 )$$

where r is the angular distribution in degrees, Iₒ is a relative intensity scalar, ws is a gaussian weighting parameter, and S is a parameter, which can shape the light from platykurtic with flatness in lower distribution angles to high kurtosis (e.g., S=1.5). In the design distribution 9009 illustrated in FIG. 9D, the light pattern produces a generally flat fill from center to edge with a quick fall off after 50%.

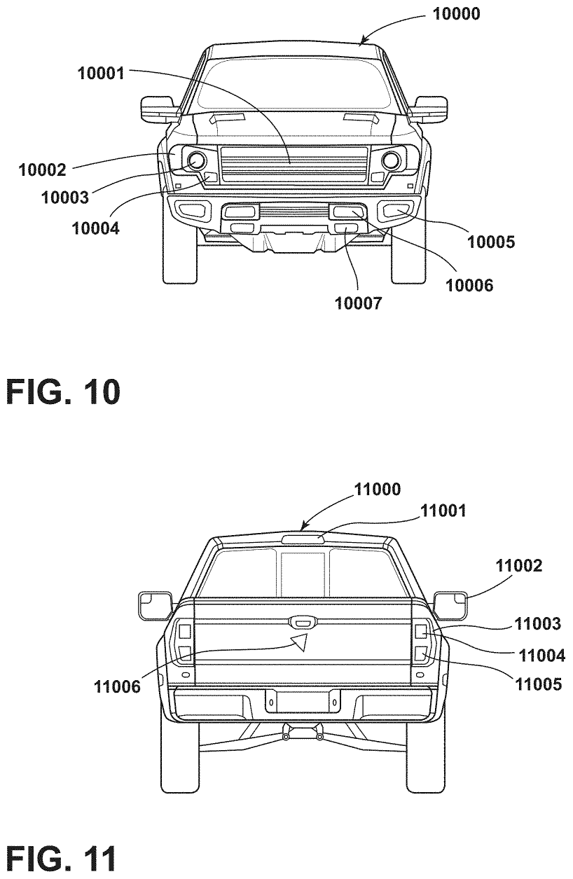

FIG. 10 depicts an advanced lighting system comprised of display element tiles comprised of wavelength conversion devices including wavelength converting lenses (described herein) installed on the front of a vehicle 10000.

The lighting display elements include, but are not limited to, lighted display grilles 10001, animated running and signal lights 10002, dynamic headlight LED arrays 10003, dynamic marker, signal, and hazard lights 10004, animated display fog light systems, secondary fog lights 10006, and projection fog and hazard lights 10007.

FIG. 11 depicts an advanced lighting system including display element tiles comprising wavelength conversion devices including wavelength converting lenses and mini-chip LED's (described herein) installed on a rear of a vehicle 11000.

Lighting display elements include, but are not limited to, center high mounted stop 11001, driver assistance lights for blind spot and proximity, turn signal 11002, and animated projection of pictorials on the ground or proximity of the vehicle.

Additionally, animated tail, and stop lights 11004, reverse lights 11005, and emblems 1006 can be enhanced using wavelength converter optics comprised of multiple species of particles mixed to produce both luminescence and lighting distribution control.

Each lighting system may provide information, such as by providing messaging, warnings, navigation, guidance, weather, and social communication between vehicles or vehicle to human.

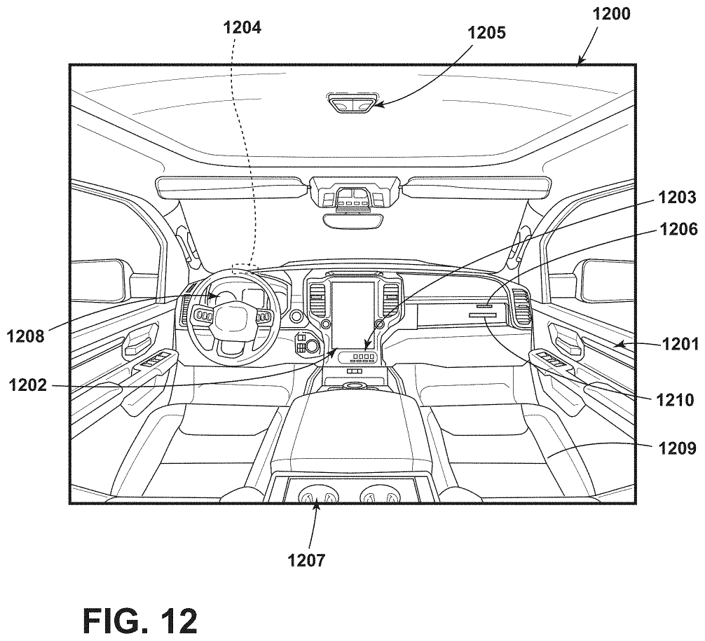

Further, as illustrated in FIG. 12, depicts an advanced lighting system including display element tiles comprising wavelength conversion devices including wavelength converting lenses and mini-chip LED's (described herein) installed on an interior of a vehicle 1200. As illustrated, the lighting display elements may be configured as an ambient light 1201, a backlight 1202 for a user interface 1203, a component of a heads-up display 1204, a dome light 1205, a feature light 1206, a cupholder light 1207, a dashboard indicator 208, an interior light device 1209 positioned along contours of vehicle seats, door panels, consoles, and other interior vehicle surfaces, an emblem 1210, and/or any other type of lighting system. It will be appreciated that the listed locations are for reference to potential locations. As such, the lighting system may be operably coupled with any other portion of the vehicle 1200 without departing from the teachings of the present disclosure. Further, it will also be appreciated that the lighting system may be used in implementations that are remote from the vehicle 1200. In such instances, the lighting system may include any feature disclosed herein without departing from the scope of the present disclosure.

In some examples, the lighting system may include one or more light sources, optical systems, electronic drivers, and/or sensors. Moreover, the lighting system may include and/or be operably coupled with a controller. In general, the controller may comprise any suitable processor-based device known in the art, such as a computing device or any suitable combination of computing devices. Thus, in several embodiments, the controller may include one or more processor(s) and associated memory device(s) configured to perform a variety of computer-implemented functions. It will be appreciated that, in several embodiments, the controller may correspond to an existing controller of the vehicle, or the controller may correspond to a separate processing device. For instance, in some embodiments, the controller may be implemented within the lighting system to allow for the disclosed lighting system to be implemented without requiring additional software to be uploaded onto existing control devices of the vehicle. In various examples, the lighting system may be capable of providing various functions, such as illumination of nearby objects, illumination of the vehicle (or a portion thereof) for detection by nearby objects, messaging, warnings, navigation, guidance, weather, social communication, and/or any other function. In addition, the lighting system may be configured to provide static and/or dynamic lighting characteristics. As used herein, static lighting characteristic means that a lighting pattern may remain consistent for a defined amount of time and a dynamic lighting characteristic means that a lighting pattern is altered during the defined amount of time.

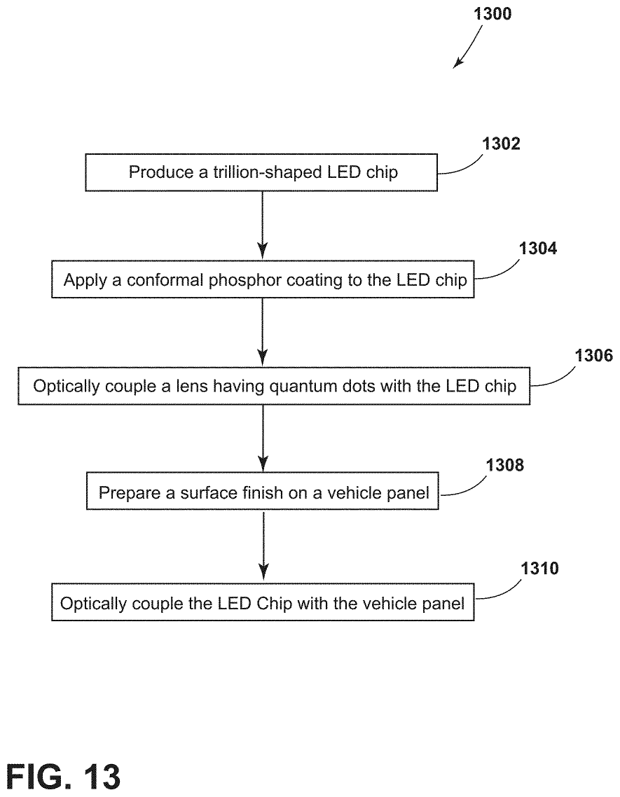

Now referring to FIGS. 13, a method for manufacturing a wavelength conversion device is provided in accordance with aspects of the present subject matter. In general, the method 1300 will be described herein with reference to the lighting system described herein. However, it will be appreciated that the disclosed method 1300 may be implemented with lighting systems having any other suitable configurations. In addition, although FIG. 13 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present disclosure.

As shown in FIG. 13, at (1302), the method 1300 can include producing a trillion-shaped LED chip that comprises three lateral sides to improve light extraction at a small size. In some instances, producing the trillion-shaped LED chip can further include producing edge bevels on the LED chip to reduce backscatter due to total internal reflection at a sharp corner. In various examples, the bevels may be produced through laser scribing and/or diamond sawing while dicing the LED wafer.

At (1304), the method 1300 can include applying a conformal phosphor coating directly or indirectly to the LED chip to improve thermal dissipation through the sapphire substrate chip by directing the heat through the PCB interconnect and substrate.

At (1306), the method 1300 can include optically coupling a lens having quantum dots with the LED chip. By combining conformal phosphor coatings with quantum dots a wide variety of spectra, CCT, colors, and CRI are possible. For example, the spectra can produce an ideal white 5000K, with high color rendition greater than or equal to 95 CRI. The exiting light rays through the lens may be a combination of colors that create an ensemble of color or superposition of blended spectra to produce high uniformity broad-band white which replicates any color in reflection.

At (1308), the method 1300 can include preparing a surface finish on a vehicle panel, which may be positioned on an exterior portion of the vehicle and/or within an interior portion of the vehicle. In some instances, the surface finish may provide one or more channels for light emitted from the LED chip to pass through a surface finish of the vehicle panel. For instance, in some examples, the vehicle panel may include a substrate and one or more finishing materials (e.g., paint, clear coat, etc.) positioned on the substrate. In such instances, the surface finish may allow for light to emanate through the substrate and/or the one or more finishing materials.

In various examples, preparing a surface finish on a vehicle panel can further include laser ablating the vehicle panel. In such instances, the laser ablation can entail selecting a wavelength of laser radiation, a laser pulse length, a laser energy density and/or a sufficient number of laser pulses delivered to a specific area of the vehicle panel to be ablated to obtain a patterned layer. These parameters are selected to be compatible with the physical properties of a portion of the vehicle panel to be ablated and any other portion of the vehicle panel not to be ablated. These properties may include the optical absorption coefficient and optical index of refraction of the portion of the vehicle panel to be ablated at the specific laser wavelength and any other portion of the vehicle panel not to be ablated at the specific wavelength; the heat capacity of the portion of the vehicle panel to be ablated and the heat capacity of any other portion of the vehicle panel not to be ablated; and the thermal conductivity of the portion of the vehicle panel to be ablated and the thermal conductivity of any other portion of the vehicle panel not to be ablated.

At (1310), the method can include optically coupling the LED chip with the vehicle panel. In some cases, the LED chip may be optically coupled with a B-side of the panel. In some cases, the LED chip may be generally non-visible from an A-side of the panel when the LED chip is in the unilluminated state and emits light through the panel from the B-side to the A-side of the panel in the illuminated state. In some cases, as light emanated from the LED chip passes through the vehicle panel, the light may shift in color. As such, the method can include performing a wavelength conversion to compensate for the color shift transmission through the vehicle panel.

Applications of embodiments in the present disclosure can be applied in numerous applications and industries. For example, as noted above, the present disclosure could be used in automotive lighting systems. The lighting system may also be implemented in other transportation industries, such as unmanned vehicles, drones, hoverboards, mopeds, bicycles, motorcycles, or other mobile apparatuses. Similarly, the present disclosure may alternatively be implemented in any other illuminable device, such as branding notifications, safety notifications, protocols, and/or messages. For example, storefronts, houses, billboards, or any marketing surface can utilize the lighting system disclosed herein.

The term “software code” or “code” used herein refers to any instructions or set of instructions that influence the operation of a computer or controller. They may exist in a computer-executable form, such as vehicle code, which is the set of instructions and data directly executed by a computer's central processing unit or by a controller, or a human-understandable form, such as source code, which may be compiled to be executed by a computer's central processing unit or by a controller, or an intermediate form, such as object code, which is produced by a compiler. As used herein, the term “software code” or “code” also includes any human-understandable computer instructions or set of instructions, e.g., a script, that may be executed on the fly with the aid of an interpreter executed by a computer's central processing unit or by a controller.

This written description uses examples to disclose the technology, including the best mode, and also to enable any person skilled in the art to practice the technology, including making and using any devices or systems and performing any incorporated methods. The patentable scope of the technology is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

What is claimed is:

1. A wavelength conversion device comprising:
an LED chip;
a PCB solder mask defining an opening at least partially encompassing the LED chip; and
a lens optically coupled with the LED chip and including phosphor particles, emulsifier particles, and lens shaping particles each immersed within the lens.

2. The wavelength conversion device of claim 1, wherein the lens has a refractive index greater than or equal to 1.5.

3. The wavelength conversion device of claim 1, wherein the phosphor particles, the emulsifier particles, and the lens shaping particles are uniformly distributed within the lens.

4. The wavelength conversion device of claim 1, wherein the phosphor particles comprise one or more of YAG, LuAg, GAL, KSF, or Si₃N₄.

5. The wavelength conversion device of claim 1, wherein the emulsifier particles comprise one or more of CaF, ZrO₂, or TiO₂.

6. The wavelength conversion device of claim 1, wherein the lens shaping particles comprise one or more of hydrophobic fumed silica or SiO₂.

7. The wavelength conversion device of claim 1, wherein a particle loading of the lens shaping particles is between 1 percent and 7 percent weight %.

8. The wavelength conversion device of claim 1, wherein the opening has an oblong geometric shape in an X-Y direction, and wherein the lens has a width in the X-direction that is greater than a width in the Y direction.

9. The wavelength conversion device of claim 8, wherein the lens produces asymmetric light distribution as light from the LED chip passes through the lens.

10. The wavelength conversion device of claim 1, wherein a center section of the lens has a longer path length for light rays from the LED chip relative to one or more sides, and wherein the phosphor particle concentration by weight is reduced in the center section.

11. The wavelength conversion device of claim 1, wherein the LED chip is trillion-shaped comprising three lateral sides, and wherein the LED chip defines edge bevels between adjacent sides of the three lateral sides.

12. A method for manufacturing a wavelength conversion device, the method comprising:
producing a trillion-shaped LED chip;
applying a conformal phosphor coating to the LED chip; and
optically coupling a lens having quantum dots with the LED chip.

13. The method of claim 12, further comprising:
producing edge bevels on the LED chip.

14. The method of claim 13, wherein the bevels are produced through laser scribing or diamond sawing while dicing the LED chip.

15. The method of claim 12, wherein exiting light rays through the lens may be a combination of colors that create an ensemble of color or superposition of blended spectra to produce high uniformity broad-band white

16. The method of claim 12, further comprising:
preparing a surface finish on a vehicle panel; and
optically coupling the LED chip with a B-side of the vehicle panel.

17. A lighting system comprising:
a first wavelength conversion device comprising:
a first trillion-shaped LED chip having three lateral sides, wherein the first trillion-shaped LED chip defines edge bevels between adjacent sides of the three lateral sides; and
a first lens optically coupled with the first trillion-shaped LED chip, the first lens including a first side portion, a second side portion, and a third side portion, wherein the first and second portions are a common distance from the first trillion-shaped LED chip and the third portion is a varied distance from the first trillion-shaped LED chip.

18. The lighting system of claim 17, wherein the first lens includes phosphor particles, emulsifier particles, and lens shaping particles each immersed within the first lens.

19. The lighting system of claim 17, further comprising:
a second wavelength conversion device comprising:
a second trillion-shaped LED chip having three lateral sides, wherein the second trillion-shaped LED chip defines edge bevels between adjacent sides of the three lateral sides; and
a second lens optically coupled with the second trillion-shaped LED chip, the second lens including a first side portion, a second side portion, and a third side portion, wherein the first and second portions are a common distance from the first trillion-shaped LED chip and the third portion is a varied distance from the second trillion-shaped LED chip.

20. The lighting system of claim 17, wherein the second lens includes phosphor particles, emulsifier particles, and lens shaping particles each immersed within the second lens.
